(19) United States
(12) Patent Application Publication
(10) Pub. No.: US 2025/0386468 A1
(43) Pub. Date: Dec. 18, 2025

(54) AIR-COOLING FOR RESOURCE COMPONENTS OF DATA CENTER DEVICES

(71) Applicant: Microsoft Technology Licensing, LLC, Redmond, WA (US)

(72) Inventors: Debdeep BHATTACHARYA, Hyderabad (IN); Rudolph G. GRAHAM, Mt. Vernon, WA (US); Sunil JOHN, Bothell, WA (US)

(73) Assignee: Microsoft Technology Licensing, LLC, Redmond, WA (US)

(21) Appl. No.: 18/744,394

(22) Filed: Jun. 14, 2024

(51) Int. Cl. H05K 7/20

(52) U.S. Cl. CPC H05K 7/20836; H05K 7/20718

(57) ABSTRACT

Systems and methods are provided for implementing improved air-cooling for resource components of data center devices. A controller receives temperature sensor data from at least one temperature sensor and receives power usage data from at least one power usage sensor. The temperature sensor data corresponds to an operating temperature of resource components, while the power usage data corresponds to a combined power usage of at least the resource components and a cooling system. The controller determines at least one control level for the cooling system to optimize an output of the cooling system to reduce the operating temperature of the resource components while maintaining the combined power usage as power usage of the cooling system is increased and the power usage of the resource components is decreased due to the reduced operating temperature of the resource components. The controller causes the cooling system to operate at the determined control level.

### BACKGROUND

Devices, such as data center devices, are susceptible to lower reliability with higher power dissipation and higher temperature of its components. It is with respect to this general technical environment to which aspects of the present disclosure are directed. In addition, although relatively specific problems have been discussed, it should be understood that the examples should not be limited to solving the specific problems identified in the background.

### SUMMARY

This summary is provided to introduce a selection of concepts in a simplified form that are further described below in the detailed description section. This summary is not intended to identify key features or essential features of the claimed subject matter, nor is it intended as an aid in determining the scope of the claimed subject matter.

The currently disclosed technology, among other things, provides for improved air-cooling for resource components of data center devices. A controller or computing system receives temperature sensor data from at least one temperature sensor and receives power usage data from at least one power usage sensor. The temperature sensor data corresponds to an operating temperature of resource components, while the power usage data corresponds to a combined power usage of at least the resource components and a cooling system. The controller or computing system determines at least one control level for the cooling system to optimize an output of the cooling system to reduce the operating temperature of the resource components while maintaining the combined power usage as power usage of the cooling system is increased and the power usage of the resource components is decreased due to the reduced operating temperature of the resource components. The controller or computing system causes the cooling system to operate at the determined control level.

The details of one or more aspects are set forth in the accompanying drawings and description below. Other features and advantages will be apparent from a reading of the following detailed description and a review of the associated drawings. It is to be understood that the following detailed description is explanatory only and is not restrictive of the invention as claimed.

### BRIEF DESCRIPTION OF THE DRAWINGS

A further understanding of the nature and advantages of particular embodiments may be realized by reference to the remaining portions of the specification and the drawings, which are incorporated in and constitute a part of this disclosure.

FIG. 1 depicts an example system for implementing improved air-cooling for resource components of data center devices.

FIGS. 2A and 2B depict an example set of graphs illustrating resource component temperature variations and total server power drawn versus fan control levels when implementing improved air-cooling for resource components of data center devices.

FIG. 2C depicts an example table illustrating results indicating effectiveness of the implementation of improved air-cooling for resource components of data center devices.

FIG. 2D depicts an example set of graphs illustrating resource component temperature over time for resource components of data center devices.

FIG. 3 depicts an example method for implementing improved air-cooling for resource components of data center devices.

FIG. 4 depicts another example method for implementing improved air-cooling for resource components of data center devices.

FIG. 5 depicts a block diagram illustrating example physical components of a computing device with which aspects of the technology may be practiced.

### DETAILED DESCRIPTION OF CERTAIN EMBODIMENTS

In data centers, there is a never ending and ever-increasing demand for compute, storage, and networking power. Specifically, with interest increasing with respect to implementing artificial intelligence (“AI”) solutions, the demand for high performance computing would increase manifold in response. This higher performance comes at a cost in terms of power dissipation. With higher power dissipation, two fallouts issues arise. First, higher cooling capacity is needed. Second, higher rates of failure occur as essential components are operated at higher temperature, thus resulting in less reliable hardware. With lesser reliability, the cost for maintenance, repair, and replacement becomes higher, and downtime of servers results in overall system inefficiencies and decreases in service provisioning for AI or other implementations.

Among other things, the present technology described herein differs from implementations that utilize conventional techniques that focus on minimum (or lowest possible) fan power to sustain the server, without causing the server to become completely unresponsive and/or completely non-functional. In particular, the present technology employs a cooling implementation that balances power dissipation or power draw with control levels for the cooling system that cools the resource components of the device. In other words, the present technology focuses on moderate fan speed of operation that ensures higher reliability without changing overall power levels compared with conventional techniques. That is, a controller or computing system determines at least one control level for the cooling system to optimize an output of the cooling system to reduce the operating temperature of the resource components while maintaining the combined power usage as power usage of the cooling system is increased and the power usage of the resource components is decreased due to the reduced operating temperature of the resource component. In this manner, the reliability (and thus the longevity) of the resource components may be increased or improved at no additional cost overhead or at a minimized additional cost overhead, due to the total power draw being held relatively constant while setting the cooling system at the determined control level (e.g., optimal pulse-width modulation (“PWM”) value) for the cooling system (e.g., fans) to lower the operating temperature of the resource components.

Various modifications and additions can be made to the embodiments discussed herein without departing from the scope of the disclosed techniques. For example, while the embodiments described above refer to particular features, the scope of the disclosed techniques also includes embodiments having different combinations of features and embodiments that do not include all of the above-described features.

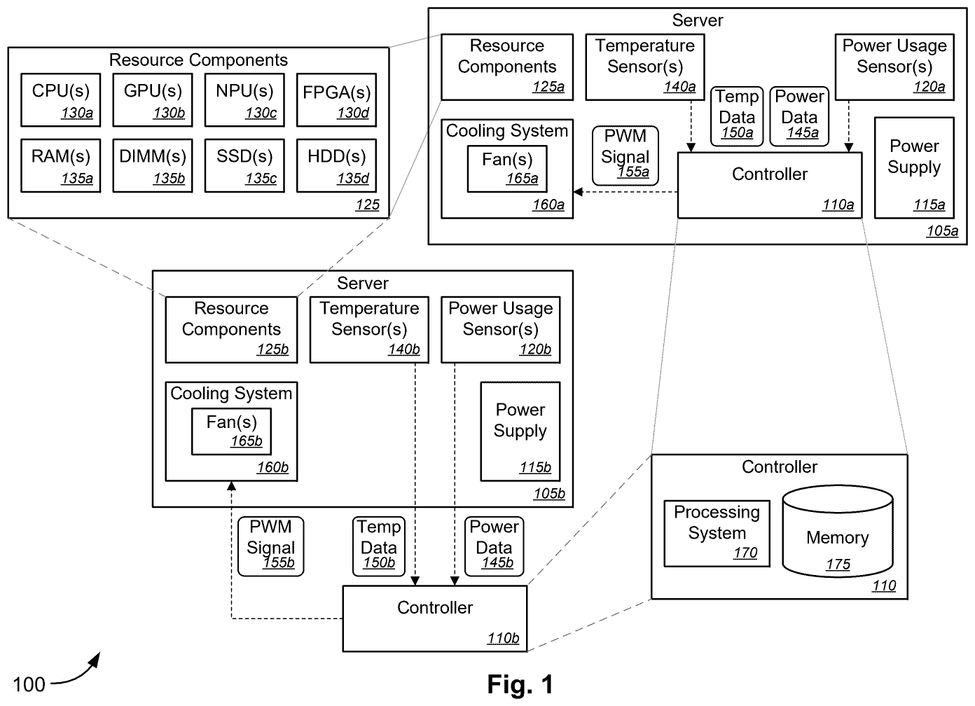

Turning to the embodiments as illustrated by the drawings, FIGS. 1-5 illustrate some of the features of methods, systems, and apparatuses for implementing data center device optimization, and, more particularly, to methods, systems, and apparatuses for implementing improved air-cooling for resource components of data center devices, as referred to above. The methods, systems, and apparatuses illustrated by FIGS. 1-5 refer to examples of different embodiments that include various components and steps, which can be considered alternatives or which can be used in conjunction with one another in the various embodiments. The description of the illustrated methods, systems, and apparatuses shown in FIGS. 1-5 is provided for purposes of illustration and should not be considered to limit the scope of the different embodiments.

FIG. 1 depicts an example system 100 for implementing improved air-cooling for resource components of data center devices. System 100 includes a first server 105a and/or a second server 105b. In some examples, system 100 further includes at least one of a first controller 110a, a first power supply 115a, a first power usage sensor(s) 120a, a first resource components 125a, a first temperature sensor(s) 140a, or a first cooling system 160a. In some cases, the first cooling system 160a includes a first fan(s) 165a. In some instances, the first power usage sensor(s) 120a and the first temperature sensor(s) 140a collectively constitute a first sensor system. In examples, system 100 alternatively or additionally includes at least one of a second controller 110b, a second power supply 115b, a second power usage sensor(s) 120b, a second resource components 125b, a second temperature sensor(s) 140b, or a second cooling system 160b. In some instances, the second cooling system 160b includes a second fan(s) 165b. In some cases, the second power usage sensor(s) 120b and the second temperature sensor(s) 140b collectively constitute a second sensor system.

In an example, as shown in FIG. 1, the first controller 110a, the first power supply 115a, the first power usage sensor(s) 120a, the first resource components 125a, the first temperature sensor(s) 140a, and the first cooling system 160a (in some cases, including the first fan(s) 165a) are contained within the first server 105a. In another example, as also shown in FIG. 1, the second power supply 115b, the second power usage sensor(s) 120b, the second resource components 125b, the second temperature sensor(s) 140b, and the second cooling system 160b (in some cases, including the second fan(s) 165b) are contained within the second server 105b, while the second controller 110b is external, yet communicatively coupled, to second server 105b. In examples, each of the first server 105a, the first controller 110a, the first power supply 115a, the first power usage sensor(s) 120a, the first resource components 125a, the first temperature sensor(s) 140a, the first cooling system 160a, and the first fan(s) 165a is similar, if not otherwise identical, to the second server 105b, the second controller 110b, the second power supply 115b, the second power usage sensor(s) 120b, the second resource components 125b, the second temperature sensor(s) 140b, the second cooling system 160b, and the second fan(s) 165b, respectively.

In examples, the resource components 125a or 125b (collectively, “resource components 125”) include at least one of a compute resource component 130 or a data storage resource component 135. In some instances, the compute resource component 130 includes at least one of a central processing unit(s) (“CPU(s)”) or a CPU-based resource component(s) 130a, a graphics processing unit(s) (“GPU(s)”) or a GPU-based resource component(s) 130b, a neural processing unit(s) (“NPU(s)”) or a NPU-based resource component(s) 130c, or a field-programmable gate array(s) (“FPGA(s)”) or a FPGA-based resource component(s) 130d. In some cases, the data storage resource component 135 includes memory components and storage components. In some examples, the memory components include at least one of a random access memory (“RAM”) device(s) or a RAM-based resource component(s) 135a, a dual in-line memory module(s) (“DIMM(s)”) or a DIMM-based resource component(s) 135b, or other memory component(s). In examples, the storage components include at least one of a solid-state drive(s) (“SSD(s)”) or a SSD-based resource component(s) 135c, a hard disk drive(s) (“HDD(s)”) or a HDD-based resource component(s) 135d, or other data storage component(s). In some examples, at least one of controller 110a or 110b (collectively, “controller 110”) includes a processing system 170 and memory 175.

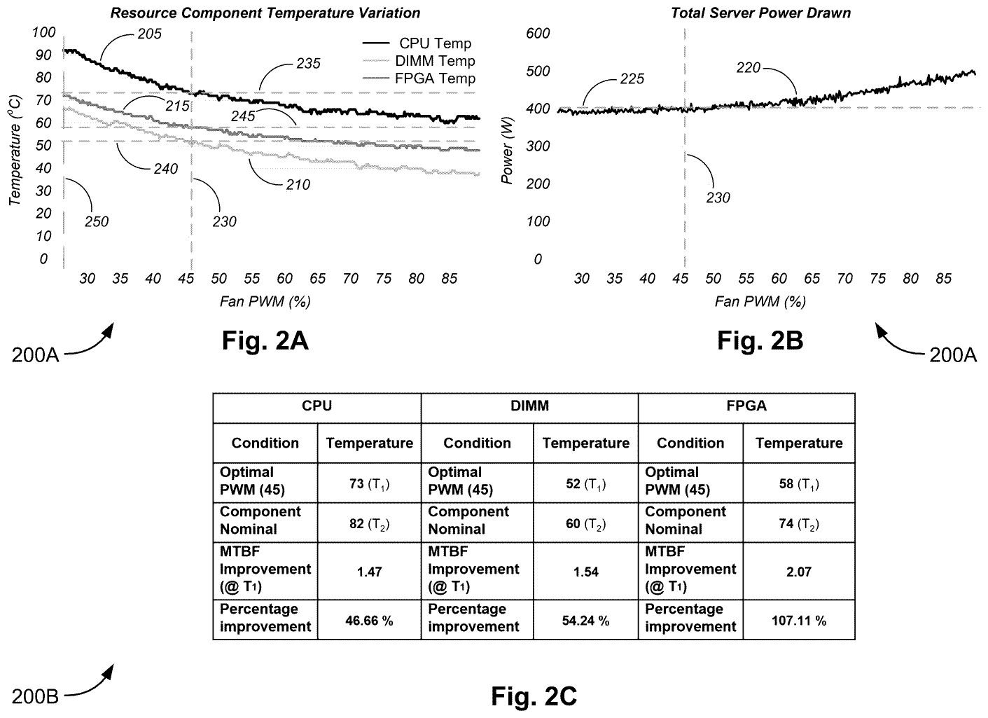

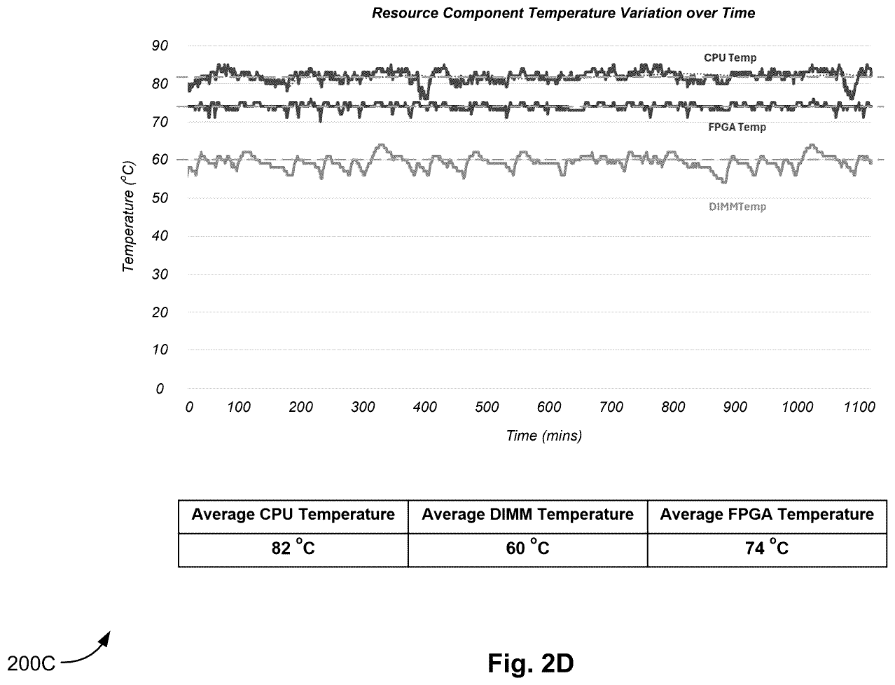

In operation, power supply 115a (or 115b) may be used to provide electrical power to at least resource components 125a (or 125b) and cooling system 160a (or 160b) (in some cases, including fan(s) 165a (or 165b)). In some instances, power supply 115a (or 115b) may also be used to provide electrical power to controller 110a (or 110b), temperature sensor(s) 140a (or 140b), and/or power usage sensor(s) 120a (or 120b). In examples, resource components 125 and cooling system 160a or 160b may draw more electrical power compared with other components of the server 105a or 105b. In some cases, some resource components among resource components 130a-130d and 135a-135d may draw more electrical power compared with other resource components among resource components 130a-130d and 135a-135d. For example, CPU(s) 130a, FPGA(s) 130d, and DIMM(s) 135b may be high power draw components, and thus are used as examples in FIGS. 2A-2C for purposes of illustration.

Power usage sensor(s) 120a (or 120b) is used to monitor electrical power provided by power supply 115a (or 115b) or electrical power drawn by components of the server 105a (or 105b), and may provide or send power usage data 145a (or 145b) to corresponding controller 110a (or 110b) (as denoted, in FIG. 1, by dash-lined arrow from power usage sensor(s) 120a (or 120b) to controller 110a (or 110b)). Temperature sensor(s) 140a (or 140b) is used to monitor the temperature of resource components 125a (or 125b) of server 105a (or 105b). In an example, temperature sensor(s) 140a (or 140b) is used to monitor a single temperature zone covering the resource components 125a (or 125b) of the server 105a (or 105b). In another example, temperature sensor(s) 140a (or 140b) is used to monitor a plurality of temperature zones covering corresponding groups of the resource components 125a (or 125b) of the server 105a (or 105b). In either case, temperature sensor(s) 140a (or 140b) may provide or send temperature data 150a (or 150b) to corresponding controller 110a (or 110b) (as denoted, in FIG. 1, by dash-lined arrow from temperature sensor(s) 140a (or 140b) to controller 110a (or 110b)).

Based on the temperature data 150a (or 150b) and the power usage data 145a (or 145b), the controller 110a (or 110b) may determine at least one control level (e.g., a single control level where a single temperature zone is used or a plurality of control levels where a plurality of temperature zones is used) for the cooling system 160a (or 160b) (in some cases, for fan(s) 165a (or 165b)). In examples, the at least one control level is determined to optimize an output of the cooling system 160a (or 160b) to reduce the operating temperature of the resource components 125a (or 125b) while maintaining the combined power usage of the components of server 105a (or 105b) (including the at least resource components 125a (or 125b) and the cooling system 160a (or 160b)) as power usage of the cooling system 160a (or 160b) is increased and the power usage of the resource components 125a (or 125b) is decreased due to the reduced operating temperature of the resource components 125a (or 125b) and/or due to reduced leakage current at reduced temperature. In some examples, the controller 110a (or 110b) causes the cooling system 160a (or 160b) (in some cases, causing the fan(s) 165a (or 165b)) to operate at the determined control level, in some instances, using a PWM signal 155a (or 155b) for controlling the cooling system 160a (or 160b) and/or for controlling the fan(s) 165a (or 165b)) to operate at the determined control level. FIGS. 2A and 2B depict example control levels in the form of fan PWM levels (in this case, in terms of percentage values).

In examples, the temperature sensor(s) 140a (or 140b) and the power usage sensor(s) 120a (or 120b) are used to continually monitor the temperature of the resource components 125a (or 125b) of the server 105a (or 105b) or the temperature of server 105a (or 105b) and the electrical power provided by the power supply 115a (or 115b) or the electrical power drawn by components of the server 105a (or 105b), respectively. The resultant temperature data 150a (or 150b) and power usage data 145a (or 145b) are used by the controller 110a (or 110b) to determine updated control level(s) and to cause or control the cooling system 160a (or 160b) and/or the fan(s) 165a (or 165b)) to operate at the determined updated control level(s), in some cases, using updated PWM signals 155a (or 155b).

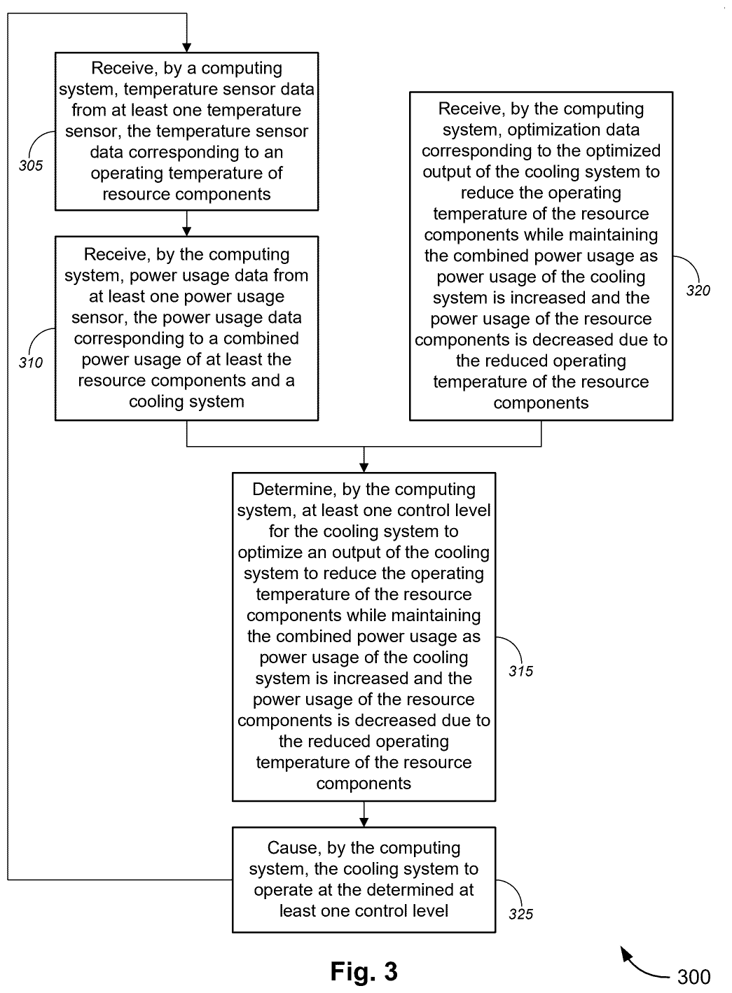

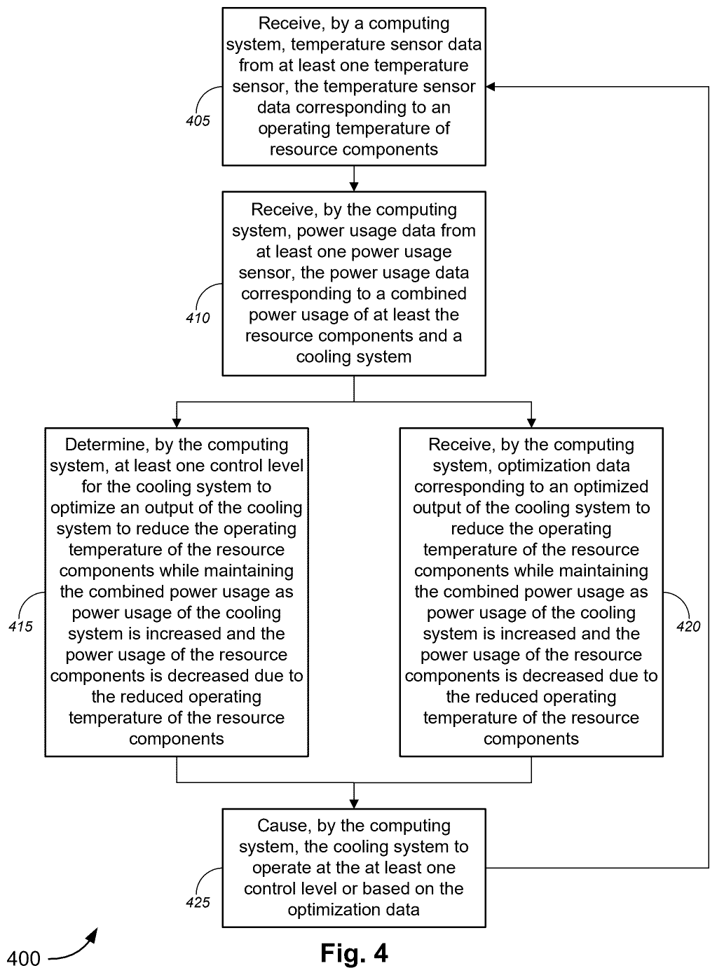

With reference to FIGS. 2A-4, controller 110, 110a, or 110b may perform methods for implementing improved air-cooling for resource components of devices, such as data center devices (like servers or other components). For example, example graphs 200A and example table 200B as described below with respect to FIGS. 2A-2C, and example methods 300 and 400 as described below with respect to FIGS. 3 and 4 may be applied with respect to the operations of system 100 of FIG. 1.

FIGS. 2A and 2B depict an example set of graphs 200A illustrating resource component temperature variations and total server power drawn versus fan control levels when implementing improved air-cooling for resource components of data center devices. The resource components referred to with respect to FIGS. 2A and 2B include resource components 125 of FIG. 1, including CPU(s) 130a, GPU(s) 130b, NPU(s) 130c, FPGA(s) 130d, RAM(s) 135a, DIMM(s) 135b, SSD(s) 135c, and/or HDD(s) 135d. In examples, data center devices include servers, such as servers 105a and/or 105b of FIG. 1. Although servers are described herein, any other suitable data center devices that have resource components, sensors, and cooling systems may be used. In examples, due to data center guidelines or similar guidelines, the PWM of the fans can be increased to an extent that it does not exceed a limit value of 158 cubic feet per minute per kilowatt (“CFM/kW”) and that it does not generate too much acoustic noise.

Temperature can negatively impact the reliability of electronic components, such as the resource components described above, through a variety of mechanisms including electro-migration, high temperature stress, thermal fatigue, drift of parameters of devices (e.g., frequency, current, and/or voltage), solder joint failures, ionic effects, increase in leakage current, thermal stress on a printed circuit board (“PCB”) on which the electronic components are mounted, bond-wire fatigue, and/or electrical overstress. Models that may be used to model failure of semiconductor devices include the Arrhenius Model, the Thermo-Mechanical Stress Model, the Eyring Model, the Peck Model, the Reich-Hakim Model, the Lawson Model, and other similar models. For simplicity and measuring only temperature effect on reliability (while controlling other effects such as relative humidity, thermo-mechanical stress, or similar effects), the Arrhenius Model is used herein as an example. The Arrhenius Model is given by the following equation:

$${λ}_{t} = {λ}_{0} {e}^{- {E}_{a} / kT} , \qquad ( Eqn . 1 )$$

where λₜ is a failure rate of a device at a temperature t, λ₀ is a constant of proportionality, Eₐ is an activation energy of the failure mechanism, k is the Boltzmann constant (8.62×10⁻⁵ electronvolt per Kelvin (“eV/K”)), and T is a temperature in Kelvin. In examples, failure rates may include component and non-component failure mechanisms that indicate the reliability of a device, as given, e.g., by the following equation:

$${λ}_{Device} = {λ}_{d} + {λ}_{s} + {λ}_{m} + {λ}_{p} + {λ}_{z} + \sum {n}_{i} {λ}_{i} , \qquad ( Eqn . 2 )$$

where λ_{d} is a failure rate due to design errors, λₛ is a failure rate due to software bugs, λₘ is a failure rate due to manufacturing errors, λₚ is a failure rate due to process issues, λ_{z} is a failure rate due to other issues, nᵢ is a number of a particular type of component i on the device (or on a PCB of the device) and λᵢ is a failure rate of the component i.

As shown in FIG. 2A, temperature variations of resource components relative to fan PWM signals are shown, with CPU temperatures 205, DIMM temperatures 210, and FPGA temperatures 215 decreasing as fan PWM percentage values are increased. However, as shown in FIG. 2B, as fan PWM percentage values increase, the total or overall server power draw 220 increases. With sufficiently high fan PWM values, the increase in total or overall server power draw 220 may increase, thus increasing the operational costs involved in operating the cooling system and the resource components. Such increase in operational costs may outweigh the advantages in terms of improvements in operation of the resource components and/or reliability of the resource components with the decreases in operational temperatures of the resource components due to the increases in airflow from increases in fan speed as controlled by the increased fan PWM signals. As described herein with respect to FIGS. 1, 3, and 4, the controller or computing system determines an optimal control level (in this case, an optimal fan PWM signal) that optimizes an output of the cooling system to reduce the operating temperature of the resource components while maintaining the combined power usage as power usage of the cooling system is increased and the power usage of the resource components is decreased due to the reduced operating temperature of the resource components.

FIG. 2C depicts an example table 200C illustrating results indicating effectiveness of the implementation of improved air-cooling for resource components of data center devices. Referring to the CPU, DIMM, and FPGA whose respective temperature variations versus fan PWM values are shown in FIG. 2A, example table 200C depicts corresponding conditions and their respective temperatures. For example, as shown in FIGS. 2A-2C, with an optimal PWM value (e.g., fan PWM value, in this case, at about 45%, as shown by dash line 230b in FIG. 2B) that balances a cooler operational temperature of the resource components with total server power draw may be a fan PWM value at which the total server power draw is held relatively constant (in this case, at about 400 W, as shown by dash line 225 in FIG. 2B). With reference to FIGS. 2A and 2C, at the optimal PWM value (in this case, at about 45%, as shown by dash line 230a in FIG. 2A), the CPU temperature 205 is reduced to about 73° C. (T₁) (as shown by dash line 235 in FIG. 2A) from a component nominal temperature of about 82° C. (T₂) for the CPU at an initial fan PWM value (in this case, as shown by long-dash line 250 in FIG. 2A). At the optimal PWM value (in this case, at about 45%), the DIMM temperature 210 is reduced to about 52° C. (T₁) (as shown by dash line 240 in FIG. 2A) from a component nominal temperature of about 60° C. (T₂) for the DIMM at the initial fan PWM value. At the optimal PWM value (in this case, at about 45%), the FPGA temperature 215 is reduced to about 58° C. (T₁) (as shown by dash line 245 in FIG. 2A) from a component nominal temperature of about 74° C. (T₂) for the FPGA at the initial fan PWM value.

Reliability of a device (or a resource component of the device) may be determined or calculated based on an annual failure rate (“AFR”), in some cases, using the Arrhenius Model described above. AFR represents the number of failures per year for that device (or that resource component of the device), and increases with increasing operating temperature. Reliability of the device (or the resource component of the device) may alternatively or additionally be determined or calculated based on a mean time before failure (“MTBF”) (also referred to a mean time to failure (“MTTF”)). MTBF represents the number of hours before failure of that device (or that resource component of the device), and decreases with increasing operating temperature. MTBF may be calculated based on a previous MTBF multiplied by a ratio between a current AFR and a previous AFR. Thus, an improvement in MTBF may be calculated by a current AFR divided by a previous AFR.

Referring back to FIG. 2C, for the CPU, the AFR that is calculated for temperature T₁ (in this case, 73° C.) for the optimal PWM (in this case, PWM value of 45%) is divided by the AFR that is calculated for temperature T₂ (in this case, 82° C.) for the component nominal temperature. In this case, the MTBF improvement is 1.66, which provides a percentage improvement of 65.92% for the CPU. Similarly, for the DIMM, the AFR that is calculated for temperature T₁ (in this case, 52° C.) for the optimal PWM (in this case, PWM value of 45%) is divided by the AFR that is calculated for temperature T₂ (in this case, 60° C.) for the component nominal temperature. In this case, the MTBF improvement is 2.03, which provides a percentage improvement of 103.29% for the DIMM. Likewise, for the FPGA, the AFR that is calculated for temperature T₁ (in this case, 58° C.) for the optimal PWM (in this case, PWM value of 45%) is divided by the AFR that is calculated for temperature T₂ (in this case, 74° C.) for the component nominal temperature. In this case, the MTBF improvement is 1.90, which provides a percentage improvement of 89.79% for the FPGA.

In examples, for a device that has 2 CPUs each with a base AFR of 0.15%, 16 DIMMs each with a base AFR of 0.4%, 2 FPGAs each with a base AFR of 0.9%, and 8 SSDs each with a base AFR of 0.4%, an AFR for the device is calculated as follows:

$${λ}_{Device} = ( 2 \times 0.15 \% ) + ( 16 \times 0.4 \% ) + ( 2 \times 0.9 \% ) + ( 8 \times 0.4 \% ) = 11.7 \% . \qquad ( Eqn . 3 )$$

Assuming that an SSD has a similar MTBF improvement similar to that of a DIMM, for the device as referred to in FIGS. 2A-2C, and using the MTBF improvements in the example table 200B of FIG. 2C, a previous AFR for the device is calculated as follows:

$${λ}_{Device}^{′} = \frac{( 2 \times 0.15 \% )}{1.47} + \frac{( 16 \times 0.4 \% )}{1.54} + \frac{( 2 \times 0.9 \% )}{2.07} + \frac{( 8 \times 0.4 \% )}{1.54} = 7.3 \% . \qquad ( Eqn . 4 )$$

As described above, for this device, the MTBF improvement is calculated by dividing 11.7% by 7.30%, which results in an improvement in MTBF of 1.60 or 60%. Accordingly, to address the lower reliability with higher power dissipation and temperature of components, the various embodiments increase the reliability of the components at no additional or minimized additional cost overhead (as the total power draw is held constant while setting the cooling system at the optimal fan PWM to lower the operating temperature of the resource components).

FIG. 2D depicts an example set of graphs 200C illustrating resource component temperature over time for resource components of data center devices. In particular, the example set of graphs 200C of FIG. 2D depicts resource component temperature over time for CPUs, DIMMs and FPGAs, under similar stress conditions as those of corresponding resource components described above with respect to FIGS. 2A and 2B, although with conventional fan control algorithm in place. As shown in FIG. 2D, the temperatures for the CPUs, DIMMs, and FPGAs vary over time, with average temperatures of 82, 60, and 74° C., respectively.

FIG. 3 depicts an example method 300 for implementing improved air-cooling for resource components of data center devices. In the example of FIG. 3, method 300, at operation 305, includes a computing system (e.g., controller 110a or 110b of FIG. 1) receiving temperature sensor data (e.g., temperature data 150a or 150b of FIG. 1) from the at least one temperature sensor (e.g., temperature sensor(s) 140a or 140b of FIG. 1). In some examples, the temperature sensor data corresponds to an operating temperature of resource components (e.g., resource components 125, 125a, and 125b of FIG. 1). At operation 310, method 300 includes the computing system receiving power usage data (e.g., power usage data 145a or 145b of FIG. 1) from the at least one power usage sensor (e.g., power usage sensor(s) 120a or 120b of FIG. 1). The power usage data corresponds to a combined power usage of at least the resource components and a cooling system (e.g., cooling systems 160a and 160b of FIG. 1).

In some examples, the resource components include at least one of a compute resource component (e.g., compute resource components 130a-130d of FIG. 1) or a data storage resource component (e.g., data storage resource components 135a-135d of FIG. 1). In some instances, the compute resource component includes at least one of a CPU-based resource component (e.g., CPU(s) 130a of FIG. 1), a GPU-based resource component (e.g., GPU(s) 130b of FIG. 1), an NPU-based resource component (e.g., NPU(s) 130c of FIG. 1), or an FPGA-based resource component (e.g., FPGA(s) 130d of FIG. 1). In some cases, the data storage resource component includes at least one of a RAM-based resource component (e.g., RAM(s) 135a of FIG. 1), a DIMM-based resource component (e.g., DIMM(s) 135b of FIG. 1), an SSD-based resource component (e.g., SSD(s) 135c of FIG. 1), or an HDD-based resource component (e.g., HDD(s) 135d of FIG. 1).

Method 300, at operation 315, further includes the computing system determining at least one control level for the cooling system to optimize an output of the cooling system to reduce the operating temperature of the resource components while maintaining the combined power usage as power usage of the cooling system is increased and the power usage of the resource components is decreased due to the reduced operating temperature of the resource components. In some examples, at operation 320, method 300 includes the computing system receiving optimization data corresponding to the optimized output of the cooling system to reduce the operating temperature of the resource components while maintaining the combined power usage as power usage of the cooling system is increased and the power usage of the resource components is decreased due to the reduced operating temperature of the resource components. In examples, determining the at least one control level for the cooling system (at operation 315) is based on the received optimization data (from operation 320). Method 300 further includes the computing system causing the cooling system to operate at the determined at least one control level (at operation 325). In some examples, receiving the temperature sensor data (at operation 305), receiving the power usage data (at operation 310), determining the at least one control level (at operation 315), and causing the cooling system to operate at the determined at least one control level (at operation 325) is repeated (as denoted by the arrow looping from the process at operation 325 back to the process at operation 305, and from each of the processes 305, 310, and 315 to the next in sequence).

FIG. 4 depicts another example method 400 for implementing improved air-cooling for resource components of data center devices. Although similar to method 300, method 400 differs in the manner as described below, and shown with respect to FIG. 4. In the example of FIG. 4, method 400, at operations 405 and 410 are similar, if not identical, to operations 305 and 310 of method 300, where the computing system (similar to the computing system of FIG. 3) receives the temperature sensor data from the at least one temperature sensor (at operation 405) and receives the power usage data from the at least one power usage sensor (at operation 410). In some cases, the resource components include a plurality of resource components, where the cooling system includes a plurality of groups of fans (e.g., fans 165a and 165b of FIG. 1) corresponding to a plurality of temperature zones for cooling the plurality of resource components.

In examples, method 400 either continues onto the process at operation 415 or continues onto the process at operation 420. In an example, at operation 415, method 400 further includes the computing system determining at least one control level for the cooling system to optimize an output of the cooling system to reduce the operating temperature of the plurality of resource components while maintaining the combined power usage as power usage of the cooling system is increased and the power usage of the plurality of resource components is decreased due to the reduced operating temperature of the plurality of resource components. Alternatively, in another example, at operation 420, method 400 further includes the computing system receiving optimization data corresponding to an optimized output of the cooling system to reduce the operating temperature of the plurality of resource components while maintaining the combined power usage as power usage of the cooling system is increased and the power usage of the plurality of resource components is decreased due to the reduced operating temperature of the plurality of resource components. Method 400 further includes, after either determining the at least one control level (at operation 415) or receiving the optimization data (at operation 420), causing the cooling system to operate at the at least one control level or based on the optimization data (at operation 425).

In some examples, causing the cooling system to operate at the at least one control level or based on the optimization data (at operation 425) includes using a PWM signal (e.g., PWM signal 155a or 155b of FIG. 1) for controlling the plurality of fans to operate at the at least one control level or based on the optimization data. In some instances, the at least one control level includes a single control level that controls the plurality of fans as a single temperature zone. Alternatively, the at least one control level includes a plurality of different control levels that each controls a corresponding group of fans as a corresponding one of the plurality of temperature zones.

While the techniques and procedures in methods 300, 400 are depicted and/or described in a certain order for purposes of illustration, it should be appreciated that certain procedures may be reordered and/or omitted within the scope of various embodiments. Moreover, while the methods 300, 400 may be implemented by or with (and, in some cases, are described below with respect to) the systems, examples, or embodiments 100, 200A, and 200B of FIGS. 1, 2A-2B, and 2C, respectively (or components thereof), such methods may also be implemented using any suitable hardware (or software) implementation. Similarly, while each of the systems, examples, or embodiments 100, 200A, and 200B of FIGS. 1, 2A-2B, and 2C, respectively (or components thereof), can operate according to the methods 300, 400 (e.g., by executing instructions embodied on a computer readable medium), the systems, examples, or embodiments 100, 200A, and 200B of FIGS. 1, 2A-2B, and 2C can each also operate according to other modes of operation and/or perform other suitable procedures.

As should be appreciated from the foregoing, the present technology provides multiple technical benefits and solutions to technical problems. For instance, operating devices (e.g., servers) in data centers or in other settings generally raises multiple technical problems. For instance, one technical problem includes issues with operating temperatures and power dissipation affecting the reliability of the devices. As reliability is reduced, failures of the devices occurs, which either temporarily causes the device to be brought offline for repairs or permanently damages the device to the point of requiring replacements. Another technical problem includes a situation in which use of cooling mechanisms raising the overall power draw for the devices, which increases operational costs involved in operating the cooling system and the resource components, which decreases efficiency of the devices, the data centers, or the system overall. The present technology provides for improved air-cooling for resource components of devices (such as data center devices). In particular, based on temperature data corresponding to an operating temperature of resource components of a device and based on power usage data corresponding to a combined power usage of at least the resource components and a cooling system, a controller or computing system determines at least one control level for the cooling system to optimize an output of the cooling system. Optimization of the output of the cooling system (including a plurality of fans or other air-cooling devices) seeks to reduce the operating temperature of the resource components while maintaining the combined power usage as power usage of the cooling system is increased and the power usage of the resource components is decreased due to the reduced operating temperature of the resource components. The controller or computing system then causes the cooling system to operate at the determined control level. In this manner, the reliability (and thus the longevity) of the resource components may be increased or improved at no additional cost overhead or at a minimized additional cost overhead, due to the total power draw being held relatively constant while setting the cooling system at the determined control level (e.g., optimal PWM value) to lower the operating temperature of the resource components.

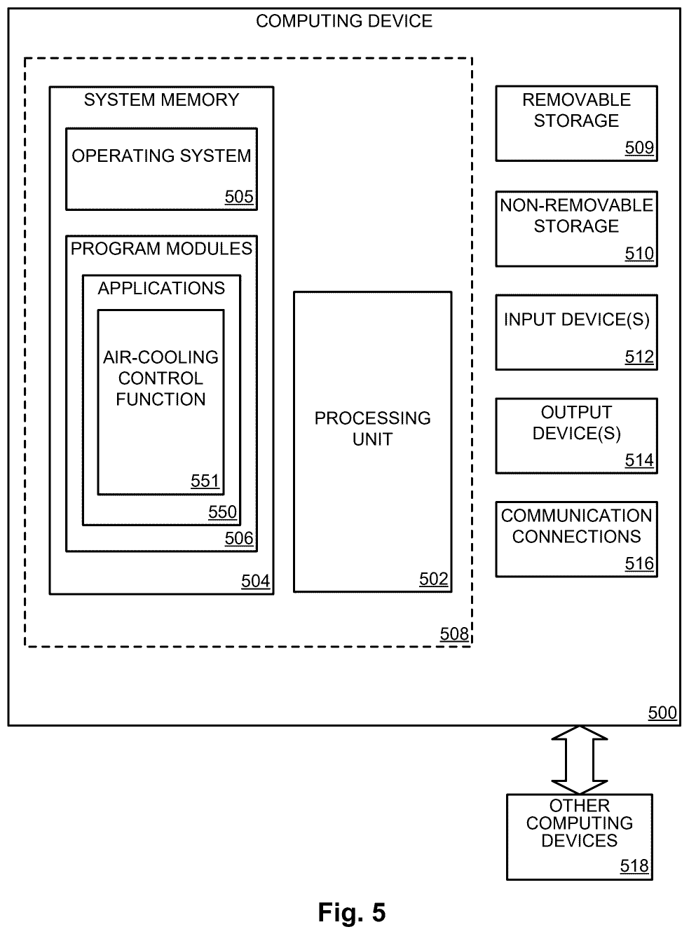

FIG. 5 depicts a block diagram illustrating physical components (i.e., hardware) of a computing device 500 with which examples of the present disclosure may be practiced. The computing device components described below may be suitable for a client device implementing the improved air-cooling for resource components of data center devices, as discussed above. In a basic configuration, the computing device 500 may include at least one processing unit 502 and a system memory 504. The processing unit(s) (e.g., processors) may be referred to as a processing system. Depending on the configuration and type of computing device, the system memory 504 may include volatile storage (e.g., random access memory), non-volatile storage (e.g., read-only memory), flash memory, or any combination of such memories. The system memory 504 may include an operating system 505 and one or more program modules 506 suitable for running software applications 550, such as air-cooling control function 551, to implement one or more of the systems or methods described above.

The operating system 505, for example, may be suitable for controlling the operation of the computing device 500. Furthermore, aspects of the invention may be practiced in conjunction with a graphics library, other operating systems, or any other application program and is not limited to any particular application or system. This basic configuration is illustrated in FIG. 5 by those components within a dashed line 508. The computing device 500 may have additional features or functionalities. For example, the computing device 500 may also include additional data storage devices (which may be removable and/or non-removable), such as, for example, magnetic disks, optical disks, or tape. Such additional storage is illustrated in FIG. 5 by a removable storage device(s) 509 and a non-removable storage device(s) 510.

As stated above, a number of program modules and data files may be stored in the system memory 504. While executing on the processing unit 502, the program modules 506 may perform processes including one or more of the operations of the method(s) as illustrated in FIGS. 3 and 4, or one or more operations of the system(s) and/or apparatus(es) as described with respect to FIGS. 1-2C, or the like. Other program modules that may be used in accordance with examples of the present disclosure may include applications such as electronic mail and contacts applications, word processing applications, spreadsheet applications, database applications, slide presentation applications, drawing or computer-aided application programs, artificial intelligence (“AI”) applications and machine learning (“ML”) modules on cloud-based systems, etc.

Furthermore, examples of the present disclosure may be practiced in an electrical circuit including discrete electronic elements, packaged or integrated electronic chips containing logic gates, a circuit utilizing a microprocessor, or on a single chip containing electronic elements or microprocessors. For example, examples of the present disclosure may be practiced via a system-on-a-chip (“SOC”) where each or many of the components illustrated in FIG. 5 may be integrated onto a single integrated circuit. Such an SOC device may include one or more processing units, graphics units, communications units, system virtualization units and various application functionalities all of which may be integrated (or “burned”) onto the chip substrate as a single integrated circuit. When operating via an SOC, the functionality, described herein, with respect to generating suggested queries, may be operated via application-specific logic integrated with other components of the computing device 500 on the single integrated circuit (or chip). Examples of the present disclosure may also be practiced using other technologies capable of performing logical operations such as, for example, AND, OR, and NOT, including mechanical, optical, fluidic, and/or quantum technologies.

The computing device 500 may also have one or more input devices 512 such as a keyboard, a mouse, a pen, a sound input device, and/or a touch input device, etc. The output device(s) 514 such as a display, speakers, and/or a printer, etc. may also be included. The aforementioned devices are examples and others may be used. The computing device 500 may include one or more communication connections 516 allowing communications with other computing devices 518. Examples of suitable communication connections 516 include radio frequency (“RF”) transmitter, receiver, and/or transceiver circuitry; universal serial bus (“USB”), parallel, and/or serial ports; and/or the like.

The term “computer readable media” as used herein may include computer storage media. Computer storage media may include volatile and nonvolatile, and/or removable and non-removable, media that may be implemented in any method or technology for storage of information, such as computer readable instructions, data structures, or program modules. The system memory 504, the removable storage device 509, and the non-removable storage device 510 are all computer storage media examples (i.e., memory storage). Computer storage media may include RAM, read-only memory (“ROM”), electrically erasable programmable read-only memory (“EEPROM”), flash memory or other memory technology, compact disk read-only memory (“CD-ROM”), digital versatile disks (“DVD”) or other optical storage, magnetic cassettes, magnetic tape, magnetic disk storage or other magnetic storage devices, or any other article of manufacture which can be used to store information and which can be accessed by the computing device 500. Any such computer storage media may be part of the computing device 500. Computer storage media may be non-transitory and tangible, and computer storage media do not include a carrier wave or other propagated data signal.

Communication media may be embodied by computer readable instructions, data structures, program modules, or other data in a modulated data signal, such as a carrier wave or other transport mechanism, and may include any information delivery media. The term “modulated data signal” may describe a signal that has one or more characteristics that are set or changed in such a manner as to encode information in the signal. By way of example, communication media may include wired media such as a wired network or direct-wired connection, and wireless media such as acoustic, RF, infrared, and other wireless media.

In this detailed description, wherever possible, the same reference numbers are used in the drawing and the detailed description to refer to the same or similar elements. In some instances, a sub-label is associated with a reference numeral to denote one of multiple similar components. When reference is made to a reference numeral without specification to an existing sub-label, it is intended to refer to all such multiple similar components. In some cases, for denoting a plurality of components, the suffixes “a” through “n” may be used, where n denotes any suitable non-negative integer number (unless it denotes the number 14, if there are components with reference numerals having suffixes “a” through “m” preceding the component with the reference numeral having a suffix “n”), and may be either the same or different from the suffix “n” for other components in the same or different figures. For example, for component #1 X05a-X05n, the integer value of n in X05n may be the same or different from the integer value of n in X10n for component #2 X10a-X10n, and so on. In other cases, other suffixes (e.g., s, t, u, v, w, x, y, and/or z) may similarly denote non-negative integer numbers that (together with n or other like suffixes) may be either all the same as each other, all different from each other, or some combination of same and different (e.g., one set of two or more having the same values with the others having different values, a plurality of sets of two or more having the same value with the others having different values).

Unless otherwise indicated, all numbers used herein to express quantities, dimensions, and so forth used should be understood as being modified in all instances by the term “about.” In this application, the use of the singular includes the plural unless specifically stated otherwise, and use of the terms “and” and “or” means “and/or” unless otherwise indicated. Moreover, the use of the term “including,” as well as other forms, such as “includes” and “included,” should be considered non-exclusive. Also, terms such as “element” or “component” encompass both elements and components including one unit and elements and components that include more than one unit, unless specifically stated otherwise.

In this detailed description, for the purposes of explanation, numerous specific details are set forth to provide a thorough understanding of the described embodiments. It will be apparent to one skilled in the art, however, that other embodiments of the present invention may be practiced without some of these specific details. In other instances, certain structures and devices are shown in block diagram form. While aspects of the technology may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the detailed description does not limit the technology, but instead, the proper scope of the technology is defined by the appended claims. Examples may take the form of a hardware implementation, or an entirely software implementation, or an implementation combining software and hardware aspects. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment of the invention, as other embodiments of the invention may omit such features. The detailed description is, therefore, not to be taken in a limiting sense.

Aspects of the present invention, for example, are described above with reference to block diagrams and/or operational illustrations of methods, systems, and computer program products according to aspects of the invention. The functions and/or acts noted in the blocks may occur out of the order as shown in any flowchart. For example, two blocks shown in succession may in fact be executed substantially concurrently or the blocks may sometimes be executed in the reverse order, depending upon the functionalities and/or acts involved. Further, as used herein and in the claims, the phrase “at least one of element A, element B, or element C” (or any suitable number of elements) is intended to convey any of: element A, element B, element C, elements A and B, elements A and C, elements B and C, and/or elements A, B, and C (and so on).

The description and illustration of one or more aspects provided in this application are not intended to limit or restrict the scope of the invention as claimed in any way. The aspects, examples, and details provided in this application are considered sufficient to convey possession and enable others to make and use the best mode of the claimed invention. The claimed invention should not be construed as being limited to any aspect, example, or detail provided in this application. Regardless of whether shown and described in combination or separately, the various features (both structural and methodological) are intended to be selectively rearranged, included, or omitted to produce an example or embodiment with a particular set of features. Having been provided with the description and illustration of the present application, one skilled in the art may envision variations, modifications, and alternate aspects, examples, and/or similar embodiments falling within the spirit of the broader aspects of the general inventive concept embodied in this application that do not depart from the broader scope of the claimed invention.

What is claimed is:

1. A system, comprising:
resource components;
a cooling system;
a sensor system including at least one temperature sensor and at least one power usage sensor; and
a controller that executes computer executable instructions that cause the controller to perform operations comprising:
receiving temperature sensor data from the at least one temperature sensor, the temperature sensor data corresponding to an operating temperature of the resource components;
receiving power usage data from the at least one power usage sensor, the power usage data corresponding to a combined power usage of at least the resource components and the cooling system;
determining a control level for the cooling system to optimize an output of the cooling system to reduce the operating temperature of the resource components while maintaining the combined power usage as power usage of the cooling system is increased and the power usage of the resource components is decreased due to the reduced operating temperature of the resource components; and
causing the cooling system to operate at the determined control level.

2. The system of claim 1, wherein the resource components comprise at least one of a compute resource component or a data storage resource component, wherein the compute resource component includes at least one of a central processing unit (“CPU”)-based resource component, a graphics processing unit (“GPU”)-based resource component, a neural processing unit (“NPU”)-based resource component, or a field-programmable gate array (“FPGA”)-based resource component, wherein the data storage resource component includes at least one of a random access memory (“RAM”)-based resource component, a dual in-line memory module (“DIMM”)-based resource component, a solid-state drive (“SSD”)-based resource component, or a hard disk drive (“HDD”)-based resource component.

3. The system of claim 1, wherein the cooling system comprises a plurality of fans.

4. The system of claim 1, wherein the operations comprise:
repeating the processes of receiving the temperature sensor data, receiving the power usage data, determining the control level, and causing the cooling system to operate at the determined control level.

5. The system of claim 1, wherein the system is a server.

6. The system of claim 1, wherein the resource components, the cooling system, and the sensor system are contained within a server, wherein the controller is external to the server.

7. The system of claim 1, wherein the operations comprise:
receiving optimization data corresponding to the optimized output of the cooling system to reduce the operating temperature of the resource components while maintaining the combined power usage as power usage of the cooling system is increased and the power usage of the resource components is decreased due to the reduced operating temperature of the resource components;
wherein determining the control level for the cooling system is based on the received optimization data;
wherein the control level corresponds to a pulse-width modulation (“PWM”) signal for controlling the cooling system.

8. A computer-implemented method, comprising:
receiving, by a computing system, temperature sensor data from at least one temperature sensor, the temperature sensor data corresponding to an operating temperature of a plurality of resource components;
receiving, by the computing system, power usage data from at least one power usage sensor, the power usage data corresponding to a combined power usage of at least the plurality of resource components and a cooling system;
performing one of:
determining, by the computing system, at least one control level for the cooling system to optimize an output of the cooling system to reduce the operating temperature of the plurality of resource components while maintaining the combined power usage as power usage of the cooling system is increased and the power usage of the plurality of resource components is decreased due to the reduced operating temperature of the plurality of resource components; or
receiving, by the computing system, optimization data corresponding to an optimized output of the cooling system to reduce the operating temperature of the plurality of resource components while maintaining the combined power usage as power usage of the cooling system is increased and the power usage of the plurality of resource components is decreased due to the reduced operating temperature of the plurality of resource components; and
causing, by the computing system, the cooling system to operate at the at least one control level or based on the optimization data.

9. The computer-implemented method of claim 8, wherein the cooling system comprises a plurality of fans.

10. The computer-implemented method of claim 9, wherein causing the cooling system to operate at the at least one control level or based on the optimization data includes using a pulse-width modulation (“PWM”) signal for controlling the plurality of fans to operate at the at least one control level or based on the optimization data.

11. The computer-implemented method of claim 9, wherein the at least one control level includes a single control level that controls the plurality of fans as a single temperature zone.

12. The computer-implemented method of claim 9, wherein the plurality of fans includes a plurality of groups of fans corresponding to a plurality of temperature zones, wherein the at least one control level includes a plurality of different control levels that each controls a corresponding group of fans as a corresponding one of the plurality of temperature zones.

13. The computer-implemented method of claim 8, further comprising:
repeating the processes of receiving the temperature sensor data, receiving the power usage data, determining the at least one control level or receiving the optimization data, and causing the cooling system to operate at the determined at least one control level.

14. The computer-implemented method of claim 8, wherein the resource components, the cooling system, the at least one temperature sensor, the at least one power usage sensor, and the controller are contained within a server.

15. The computer-implemented method of claim 8, wherein the resource components, the cooling system, the at least one temperature sensor, and the at least one power usage sensor are contained within a server, wherein the controller is external to the server.

16. A controller, comprising:
a processing system; and
memory coupled to the processing system, the memory comprising computer executable instructions that, when executed by the processing system, causes the controller to perform operations comprising:
receiving temperature sensor data from at least one temperature sensor, the temperature sensor data corresponding to an operating temperature of a plurality of resource components;
receiving power usage data from at least one power usage sensor, the power usage data corresponding to a combined power usage of at least the plurality of resource components and a cooling system;
determining at least one control level for the cooling system to optimize an output of the cooling system to reduce the operating temperature of the plurality of resource components while maintaining the combined power usage as power usage of the cooling system is increased and the power usage of the plurality of resource components is decreased due to the reduced operating temperature of the plurality of resource components; and
causing the cooling system to operate at the determined at least one control level.

17. The controller of claim 16, wherein the resource components, the cooling system, the at least one temperature sensor, the at least one power usage sensor, and the controller are contained within a server.

18. The controller of claim 16, wherein the resource components, the cooling system, the at least one temperature sensor, and the at least one power usage sensor are contained within a server, wherein the controller is external to the server.

19. The controller of claim 16, wherein the operations comprise:
receiving optimization data corresponding to the optimized output of the cooling system to reduce the operating temperature of the resource components while maintaining the combined power usage as power usage of the cooling system is increased and the power usage of the resource components is decreased due to the reduced operating temperature of the resource components;
wherein determining the at least one control level for the cooling system is based on the received optimization data.

20. The controller of claim 16, wherein the cooling system comprises a plurality of fans, wherein the at least one control level corresponds to a pulse-width modulation (“PWM”) signal for controlling the plurality of fans, wherein the resource components comprise at least one of a compute resource component or a data storage resource component, wherein the compute resource component includes at least one of a central processing unit (“CPU”)-based resource component, a graphics processing unit (“GPU”)-based resource component, a neural processing unit (“NPU”)-based resource component, or a field-programmable gate array (“FPGA”)-based resource component, wherein the data storage resource component includes at least one of a random access memory (“RAM”)-based resource component, a dual in-line memory module (“DIMM”)-based resource component, a solid-state drive (“SSD”)-based resource component, or a hard disk drive (“HDD”)-based resource component.
